(19) United States
(12) Patent Application Publication
(10) Pub. No.: US 2009/0277681 A1
(43) Pub. Date: Nov. 12, 2009

(54) EXPANSION CROSS-CONNECT ENCLOSURE

(76) Inventors: Bruce R. Musolf, Eagan, MN (US); Bryan Kennedy, Norcross, GA (US); Michael Wentworth, Belle Plaine, MN (US); Jeff Blatnik, Highlands Ranch, CO (US)

Correspondence Address: MERCHANT & GOULD PC, P.O. BOX 2903, MINNEAPOLIS, MN, 55402-0903, US

(21) Appl. No.: 12/419,171

(22) Filed: Apr. 6, 2009

Related U.S. Application Data
(60) Provisional application No. 61/042,509, filed on Apr. 4, 2008.
(60) Provisional application No. 61/079,865, filed on Jul. 11, 2008.

(51) Int. Cl. H01R 13/46; H05K 3/30

(52) U.S. Cl. 174/520; 29/832

(57) ABSTRACT

An expansion cross-connect enclosure is disclosed. The expansion cross-connect enclosure includes a housing having a front, a rear, a top, a bottom, and left and right sides, the housing having a doorway at the front. The expansion cross-connect enclosure also includes a cross-connect panel detachably connected within the housing at the rear of the housing, and an access door covering the doorway, the access door pivotally connected across the front by a door hinge. The expansion cross-connect enclosure further includes cable access openings through the rear of the housing positioned to be aligned with horizontal cable access openings of an existing cross-connect enclosure.

### CROSS-REFERENCE TO RELATED APPLICATIONS

The present application claims priority to U.S. Provisional Patent Application No. 61/042,509, filed Apr. 4, 2008, and U.S. Provisional Patent Application No. 61/079,865, filed Jul. 11, 2008. The disclosure of each of these references is hereby incorporated by reference in its entirety.

### TECHNICAL FIELD

The present disclosure relates to telecommunications system enclosures. More particularly, the present disclosure relates to an expansion cross-connect enclosure useable in telecommunications systems.

### BACKGROUND OF THE INVENTION

Telecommunications systems generally include wiring systems connecting a service provider to a large number of customer locations, such as businesses and residential locations. A cross-connect box is generally placed in an area with a number of customer locations, and is used to route voice services from a service provider to the customer locations. The cross-connect box provides a location at which subscriber lines connecting to customer locations can be selectively connected to lines routed to the service provider. Today a common method for deploying high speed broadband services is to utilize the cross-connect box as a penetration point for the broadband services. This means that the traditional cross-connect enclosure is used for more than just cross-connecting a customer to the network for voice services. In utilizing the cross-connect enclosure for broadband deployment, terminations must be available (un-used) for the digital subscriber line access multiplexer (DSLAM) input and output connections.

The number of cross-connections able to be made in a single cross-connect box is dictated by the size of that cross-connect box. If the cross-connect enclosure does not have enough available binding posts (terminal lugs) to support the input and output connections to the broadband system then the cross-connect enclosure must be expanded to support such additional terminations. To expand beyond the capacity of a single cross-connect box, a number of options are possible. The cross-connect box can be “reskinned” by field-replacing the enclosure with a larger enclosure, allowing for additional cross-connections to fit within the existing cross-connect box. Or, additional cross-connect boxes could be placed in the area of the first cross-connect box. Both of these approaches have disadvantages, especially when the operating company is faced with quickly deploying new broadband services with minimal impact on existing network and at minimal costs. In the case of a reskinning, this requires a complicated procedure which must be performed while the cross-connect box is functional and at its installed field location. In the case of a new cross-connect box, wiring becomes complex and unwieldy, because it can then become unclear which of the two cross-connect boxes is associated with a specific customer. Other disadvantages exist as well.

### SUMMARY

In general, the present disclosure relates to an expansion cross-connect enclosure designed for high speed broadband terminations. The expansion cross-connect enclosure allows a user to add the input and output terminations from the broadband system to the cross-connect enclosure and extending the functionality of existing telecommunications enclosures by adding additional components.

In a first aspect, an expansion cross-connect enclosure is disclosed. The enclosure includes a housing having a front, a rear, a top, a bottom, and left and right sides, the housing having a doorway at the front. The enclosure further includes a cross-connect panel pivotally connected to the housing by a panel hinge, the cross-connect panel affixed within the housing by a latch. The enclosure also includes an access door covering the doorway, the access door pivotally connected across the front by a door hinge. The enclosure further includes cable access openings in the rear of the housing positioned to be aligned with horizontal cable access openings of an existing cross-connect enclosure. Optionally, a cable access opening can be located in the bottom of the enclosure as well.

In a second aspect, a method of expanding capacity and functionality of a cross-connect system is disclosed. The method includes mounting a housing of an expansion cross-connect enclosure to an existing cross-connect enclosure, such that horizontal jumper access openings of the existing cross-connect enclosure align with access openings in a rear of the expansion cross-connect enclosure. The access openings of the expansion cross-connect enclosure are located on the rear of the panel toward a side opposite an access door of the expansion cross-connect enclosure. The method further includes connecting a jumper or other wire (e.g. a broadband cable or other data cable) to a cross-connect panel of the expansion cross-connect enclosure, the cross-connect panel pivotally connected to the housing by a panel hinge, and affixed within the housing by a latch. Optionally, a cable access opening can be located in the bottom of the enclosure as well.

In a third aspect, a cross-connect system is disclosed. The cross-connect system includes an existing cross-connect enclosure having a horizontal cable access opening on at least a first side and an access door on a second side adjacent the first side. The cross-connect system further includes an expansion cross-connect enclosure mounted to the existing cross-connect enclosure. The expansion cross-connect enclosure includes a housing having a front, a rear, a top, a bottom, and left and right sides, the housing having a doorway at the front. The expansion cross-connect enclosure also includes a cross-connect panel pivotally connected to the housing by a panel hinge, the cross-connect panel affixed within the housing by a latch. The expansion cross-connect enclosure further includes an access door covering the doorway, the access door pivotally connected across the front by a door hinge. The expansion cross-connect enclosure also includes a cable access opening in the rear of the housing positioned to be aligned with the horizontal cable access opening of the existing cross-connect enclosure. Optionally, a cable access opening can be located in the bottom of the enclosure as well.

In a fourth aspect, an expansion cross-connect enclosure is disclosed. The enclosure includes a housing having a front, a rear, a top, a bottom, and left and right sides, the housing having a doorway at the front. The enclosure further includes a cross-connect panel connectable to the housing via a mounting assembly, the mounting assembly including a plurality of mounting positions. The enclosure further includes an access door covering the doorway, the access door pivotally connected across the front by a door hinge. The enclosure also includes cable access openings in the rear of the housing positioned to be aligned with horizontal cable access openings of an existing cross-connect enclosure. Optionally, a cable access opening can be located in the bottom of the enclosure as well.

In a fifth aspect, a method of expanding capacity of a cross-connect system is disclosed. The method includes mounting a housing of an expansion cross-connect enclosure to an existing cross-connect enclosure in one of a plurality of mounting positions, such that horizontal jumper access openings of the existing cross-connect enclosure align with access openings in a rear of the expansion cross-connect enclosure. The access openings are located on the rear of the panel toward a side opposite an access door of the expansion cross-connect enclosure. The method also includes connecting a jumper to a cross-connect panel of the expansion cross-connect enclosure, the cross-connect panel connectable to the housing via a mounting assembly and at a plurality of mounting positions. Optionally, a cable access opening can be located in the bottom of the enclosure as well.

In a sixth aspect, a cross-connect system is disclosed. The cross-connect system includes an existing cross-connect enclosure having a horizontal cable access opening on at least a first side and an access door on a second side adjacent the first side. The cross-connect system also includes an expansion cross-connect enclosure mounted to the existing cross-connect panel. The expansion cross-connect enclosure includes a housing having a front, a rear, a top, a bottom, and left and right sides, the housing having a doorway at the front. The expansion cross-connect enclosure includes a cross-connect panel connectable to the housing via a mounting assembly, the mounting assembly including a plurality of mounting positions. The expansion cross-connect enclosure also includes an access door covering the doorway, the access door pivotally connected across the front by a door hinge, and a cable access opening in the rear of the housing positioned to be aligned with the horizontal cable access opening of the existing cross-connect enclosure. Optionally, a cable access opening can be located in the bottom of the enclosure as well.

In a seventh aspect, an expansion cross-connect enclosure is disclosed. The expansion cross-connect enclosure includes a housing having a front, a rear, a top, a bottom, and left and right sides, the housing having a doorway at the front. The expansion cross-connect enclosure also includes a cross-connect panel detachably connected within the housing at the rear of the housing, and an access door covering the doorway, the access door pivotally connected across the front by a door hinge. The expansion cross-connect enclosure further includes cable access openings through the rear of the housing positioned to be aligned with horizontal cable access openings of an existing cross-connect enclosure. Optionally, a cable access opening can be located in the bottom of the enclosure as well.

### BRIEF DESCRIPTION OF THE DRAWINGS

FIG. 1 is a front perspective view of an expansion cross-connect enclosure according to a possible embodiment of the present disclosure;

FIG. 2 is a further front perspective view of the expansion cross-connect enclosure of FIG. 1 with the cross-connect panel pivoted out from the enclosure;

FIG. 3 is a front perspective view of the expansion cross-connect enclosure of FIG. 1 having the cross-connect panel removed and the access door hinged at a left front corner;

FIG. 4 is a front plan view of the expansion cross-connect enclosure of FIG. 3;

FIG. 5 is a side plan view of the expansion cross-connect enclosure of FIG. 3;

FIG. 6 is a top plan view of the expansion cross-connect enclosure of FIG. 3;

FIG. 7 is a close-up perspective view of a portion of the expansion cross-connect enclosure of FIG. 3 illustrating features of an access door;

FIG. 8 is a side cutaway view of a portion of the expansion cross-connect enclosure of FIG. 3 illustrating mounting of a cross-connect panel within an interior area;

FIG. 9 is a front perspective view of the expansion cross-connect enclosure of FIG. 1 having the cross-connect panel removed and the access door detached for connection at a right front corner;

FIG. 10 is a close-up perspective view of a portion of the expansion cross-connect enclosure of FIG. 9 illustrating connection of the access door to the right front corner;

FIG. 11 is a front plan view of the expansion cross-connect enclosure of FIG. 9;

FIG. 12 is a side plan view of the expansion cross-connect enclosure of FIG. 9;

FIG. 13 is a top plan view of the expansion cross-connect enclosure of FIG. 9;

FIG. 14 is a perspective view of a cross-connect system including a cross-connect enclosure and an expansion cross-connect enclosure mounted thereto, according to a possible embodiment of the present disclosure;

FIG. 15 is a top plan view of a further possible cross-connect system including a cross-connect enclosure and two expansion cross-connect enclosures mounted thereto, according to a possible embodiment of the present disclosure;

FIG. 16 is a front perspective view of an expansion cross-connect enclosure according to a second possible embodiment of the present disclosure;

FIG. 17 is a rear perspective view of the expansion cross-connect enclosure of FIG. 16;

FIG. 18 is a front plan view of the expansion cross-connect enclosure of FIG. 16;

FIG. 19 is a rear plan view of the expansion cross-connect enclosure of FIG. 16;

FIG. 20 is a side plan view of the expansion cross-connect enclosure of FIG. 16;

FIG. 21 is a top plan view of the expansion cross-connect enclosure of FIG. 16;

FIG. 22 is a bottom plan view of the expansion cross-connect enclosure of FIG. 16;

FIG. 23 is a front plan view of the expansion cross-connect enclosure of FIG. 16, with the door open and a cross-connect panel mounted at a first mounting location;

FIG. 24 is a front plan view of the expansion cross-connect enclosure of FIG. 16, with the door open and a cross-connect panel mounted at a second mounting location;

FIG. 25 is a front plan view of the expansion cross-connect enclosure of FIG. 16, with the door open and a cross-connect panel mounted at a third mounting location;

FIG. 26 is a front plan view of the expansion cross-connect enclosure of FIG. 16, with the door open and a cross-connect panel mounted at a maintenance mounting position;

FIG. 27 is a front plan view of the expansion cross-connect enclosure of FIG. 16, with the door open and the cross-connect panel removed;

FIG. 28 is a front plan view of a portion of the expansion cross-connect enclosure of FIG. 27 illustrating the mounting locations available within the enclosure;

FIG. 29 is a front plan view of a portion of the expansion cross-connect enclosure of FIG. 27, further illustrating the mounting locations;

FIG. 30 is a cutaway perspective view of an interior portion of the expansion cross-connect enclosure of FIG. 16, illustrating alignment of a cross-connect panel for use in a maintenance mounting position;

FIG. 31 is a detail view of a portion of the cutaway perspective view of the interior portion illustrated in FIG. 30;

FIG. 32 is a further cutaway perspective view of an interior portion of the expansion cross-connect enclosure of FIG. 16, illustrating alignment of a cross-connect panel for use in a maintenance mounting position; and

FIG. 33 is a detail view of a portion of the cutaway perspective view of the interior portion illustrated in FIG. 32.

### DETAILED DESCRIPTION

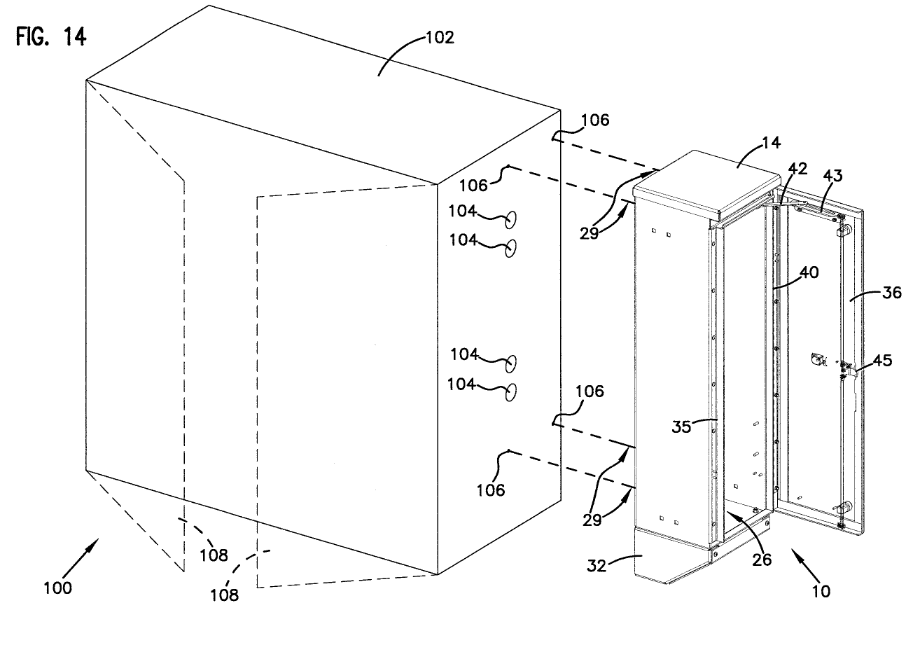

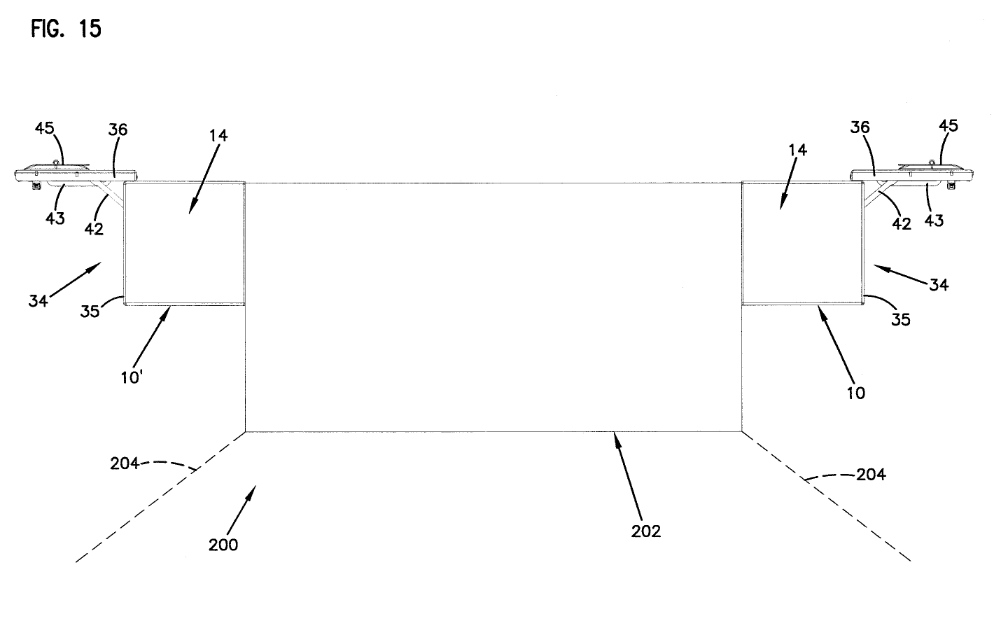

In general, the present disclosure relates to an expansion cross-connect enclosure. The expansion cross-connect enclosure contemplated by the present disclosure is generally configured to extend the functionality of an existing cross-connect enclosure, such as in the cross-connect systems shown in FIGS. 14-15, below. The expansion cross-connect enclosure 10 allows interconnection of jumpers or other electrical connections (e.g. broadband cables) between itself and an existing cross-connect enclosure, such as to introduce broadband services into a voice network.

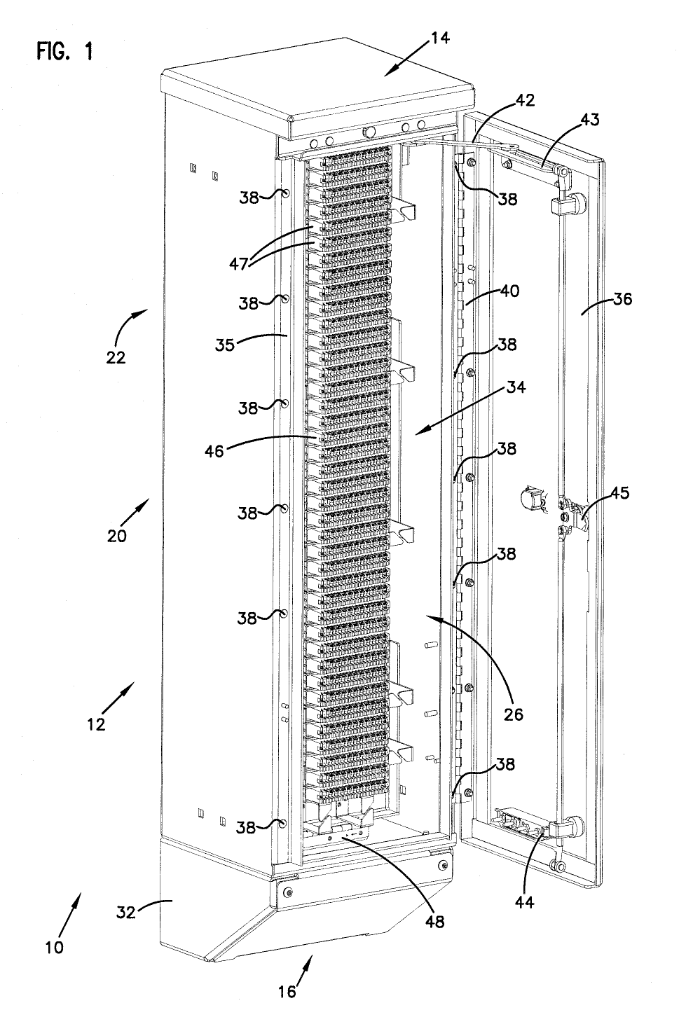

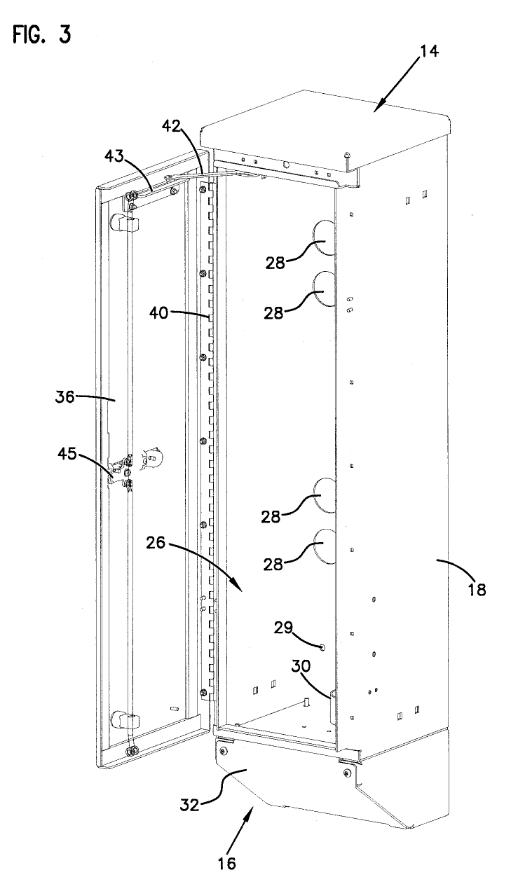

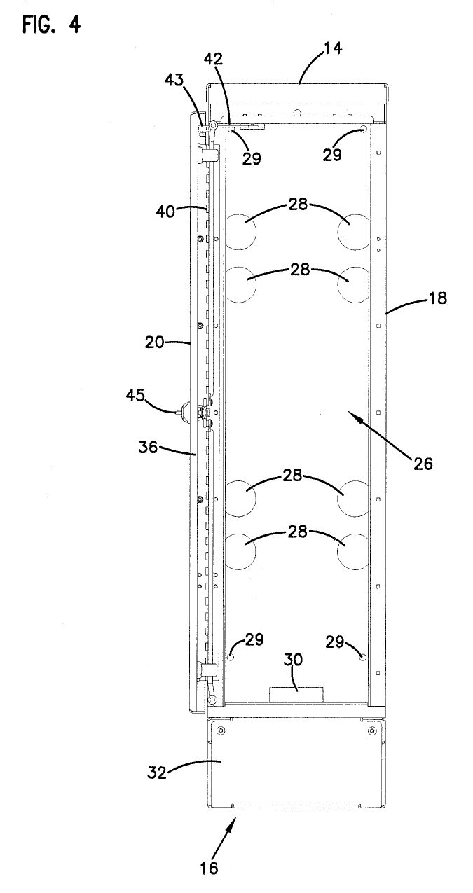

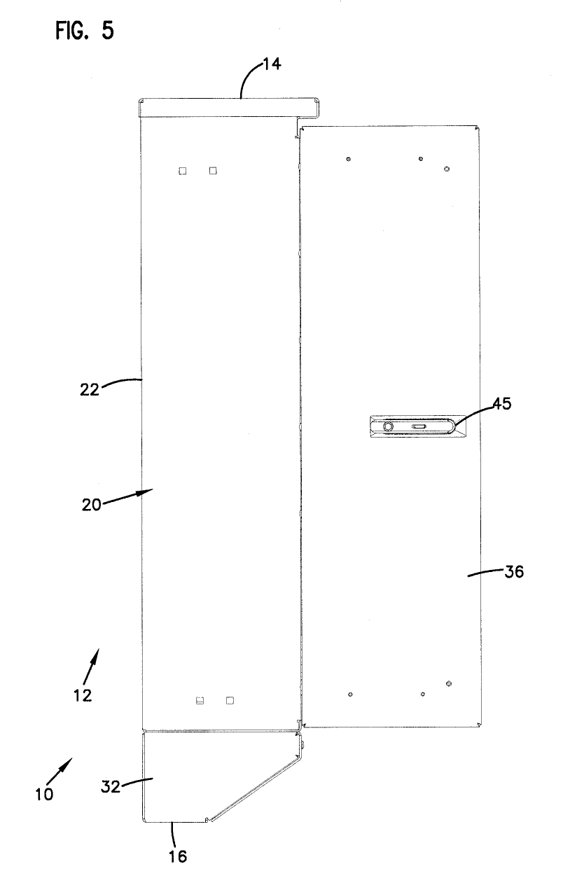

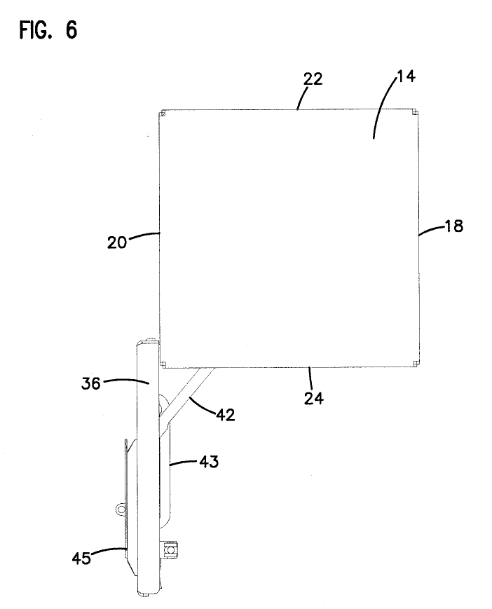

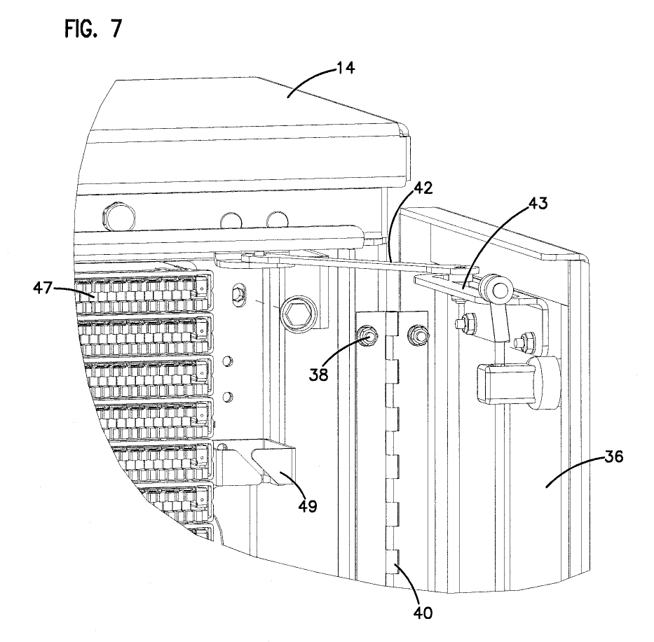

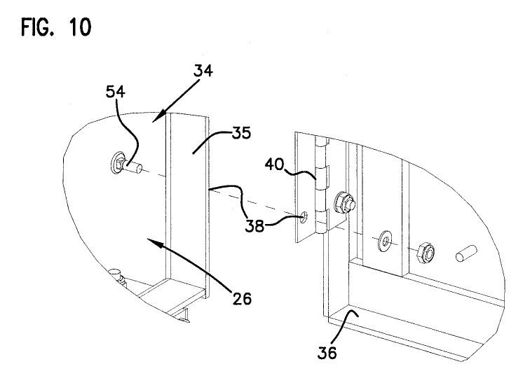

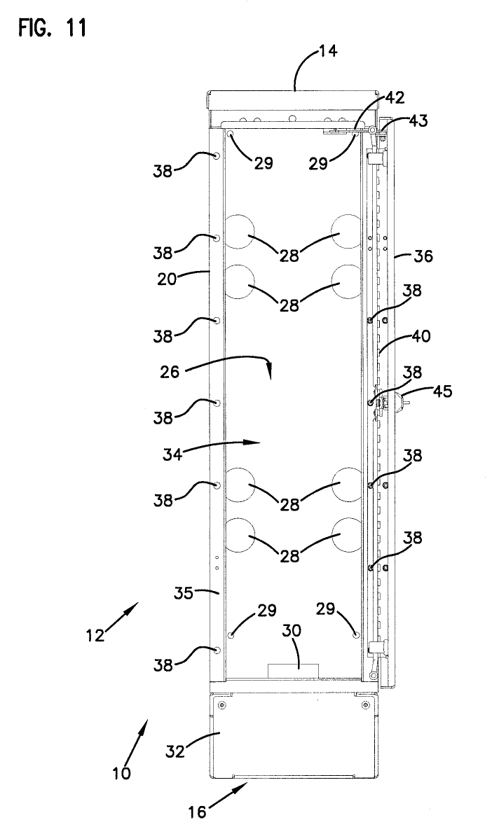

Referring now to FIGS. 1-13 generally and FIGS. 1-8 in particular, an expansion cross-connect enclosure 10 is shown, according to a possible embodiment of the present disclosure. The expansion cross-connect enclosure 10 includes a generally rectangular housing 12, which can be made from metal or other environmentally resilient materials. The housing 12 has a top 14, a bottom 16, a right side 18, a left side 20, a rear 22, and a front 24, which define an interior area 26 of the expansion cross-connect enclosure 10.

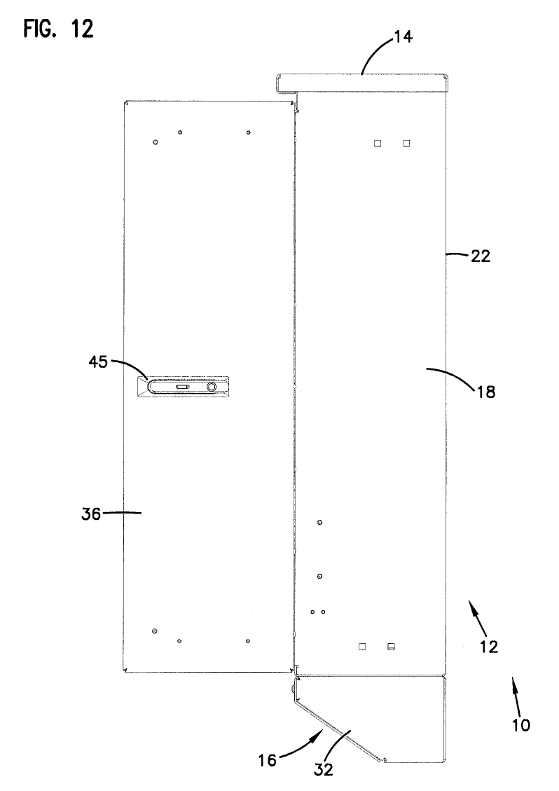

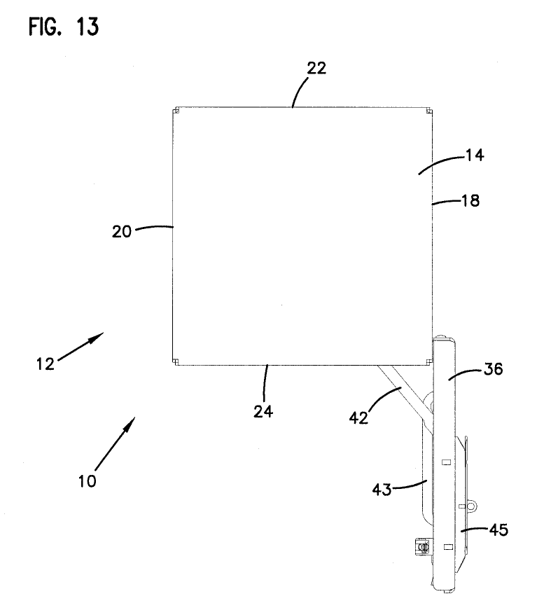

The rear 22 of the housing 12 includes cable access openings 28, and mounting locations 29. The mounting locations 29 allow the expansion cross-connect enclosure 10 to be mounted to an existing cross-connect enclosure, such as the enclosure 102 of FIGS. 12-13. The cable access openings 28 are located on the rear 22 along the right side 18 and the left side 20. In the embodiment shown, there are four cable access openings 28 along the right and left sides of the rear 22; however, more or fewer cable access openings could be used as well. The cable access openings 28 are positioned to be aligned with one or more horizontal cable access openings of an existing cross-connect panel to allow cables to be routed between the expansion cross-connect enclosure 10 and the existing cross-connect panel. In certain embodiments, the cable access openings 28 are punch-out openings which are selectively opened (e.g. by punching out an existing, partially cut portion of the housing 12 prior to installation of the expansion cross-connect enclosure 10.

The bottom 16 includes a cable access opening 30, which optionally receives a distribution cable or other underground cable not otherwise routed into an existing cross-connect panel. The bottom 16 optionally includes a mounting extension 32, which can cover the cable access opening 30 in the bottom to reduce exposure of the internal components to environmental conditions. The mounting extension 32 may be used in the case that the cable access opening 30 is not used, and all cables entering and exiting the expansion cross-connect enclosure 10 do so through the cable access openings 28 at the rear 22 of the housing 12.

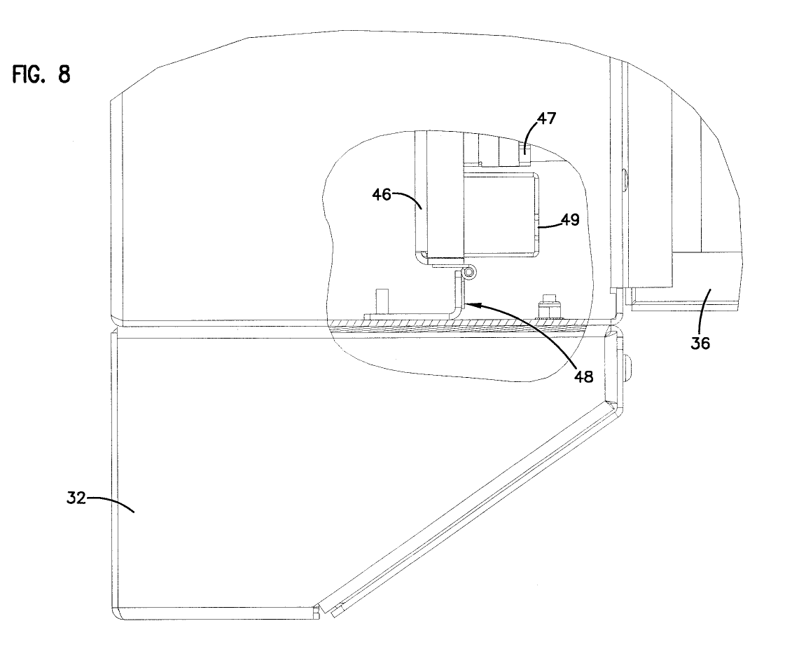

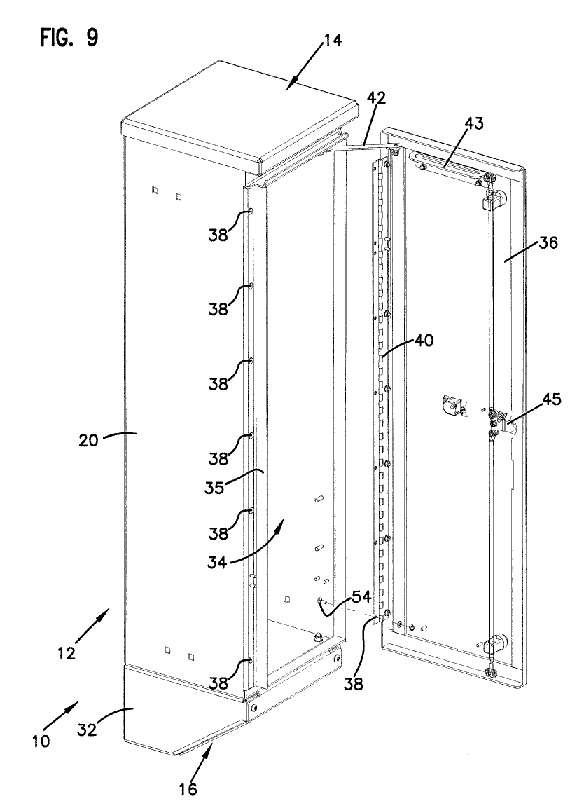

The front 24 includes a doorway 34 to which an access door 36 can be mounted. The doorway 34 is an opening defined by a door frame 35, which allows access to the interior area 26 of the expansion cross-connect enclosure 10, and is substantially the entire front 24 of the housing. The door frame 35 includes a plurality of mounting locations 38 for a door hinge 40 associated with the access door 36. The mounting locations 38 are located along an edge of the door frame 35 along the right and left sides 18, 20, respectively, of the housing. Depending upon the desired configuration of the expansion cross-connect enclosure 10, the door hinge 40 can be connected along a left or right side of the door frame 35, causing the access door 26 to pivot toward the right side or left side of the expansion cross-connect enclosure 10. When mounted along the left side of the door frame 35, the access door 26 will be upside down with respect to its position when mounted along the right side of the doorway. Additional details regarding mounting of the access door 36 to the door frame 35 are described below in conjunction with FIGS. 9-13.

The access door 36 includes a guide 42 and a connection point 44. As the access door 36 opens and closes, the guide 42 at the top of the access door slides within a slot 43 mounted to the door. The connection point 44 can receive a wired connection at one or more posts included at the point, such as a ground or signal connection for use by a technician during maintenance or adjustment of the cross-connect panel. One example connection point 44 is discussed in U.S. Pat. No. 7,200,205, entitled “Interface Device for Testing a Telecommunication Circuit”, the disclosure of which is hereby incorporated by reference in its entirety. When the pivotal orientation of the access door 36 is reversed (as described below in FIGS. 9-13) the guide 42 and connection point 44 can be removed and change places interchangeably, allowing the guide to remain along a top portion of the access door and the connection point to remain along a bottom portion of the access door.

On an opposite edge from the door hinge 40, the access door 36 includes a latch 45 that can be used by a technician to lock or unlock the access door 36, preventing unauthorized access to the interior area 26 of the expansion cross-connect enclosure 10. In the embodiment shown, the latch 45 can extend laterally from the access door 36, such that when closed, a portion of the latch slides behind a portion of the door frame 35.

As shown in FIGS. 1-2 and FIG. 8, cross-connect panel 46 is pivotally mounted in the interior area 26 by a panel hinge 48, and extends substantially along the height of the expansion cross-connect enclosure 10. The cross-connect panel 46 provides a large number of cross-connect locations 47 arranged to receive wired conductors (not shown). The cross-connect locations 47 allow connection of jumpers or other signal wires connecting between a service provider and a customer location. The jumpers or signal wires connected to the cross-connect locations can be those routed into an existing cross-connect box in which no cross-connect locations 47 are unoccupied (e.g. through cable access openings 28), or can be routed directly into the expansion cross-connect enclosure 10 through the cable access opening 30 in the bottom 16 of the housing 12. Cable clips 49 can be included on the cross-connect panel 46 as well, and can aid in routing cables to the cross-connect locations or toward the cable access openings 28, 30.

In certain embodiments, the cross-connect locations 47 correspond to cross-connection blocks, sometimes referred to as a “Krone-style connector block”, for example of “Series II” or “NT” varieties, such as are manufactured by ADC Telecommunications, Inc. Examples of such connection blocks are described in U.S. Pat. Nos. 5,494,461; 5,163,855; 5,033,974; and 4,871,330, the disclosures of which are hereby incorporated by reference in their entireties.

The cross-connect panel 46, in various embodiments, can include a circuit board containing signal routing or other circuitry elements, and can manage switching, connection, and electrical protection of telecommunications signals routed from a service provider to a large number of customer locations. In certain embodiments, the cross-connect panel can be used to introduce broadband services, such as digital subscriber line (DSL) services, into a voice network via interconnection to a DSLAM or other similar system. Further details regarding additional functionality added at a cross-connect enclosure are described in U.S. patent application Ser. No. 11/212,924, filed Aug. 26, 2005 and entitled “Enclosure for Broadband Service Delivery System”, the disclosure of which is hereby incorporated by reference in its entirety.

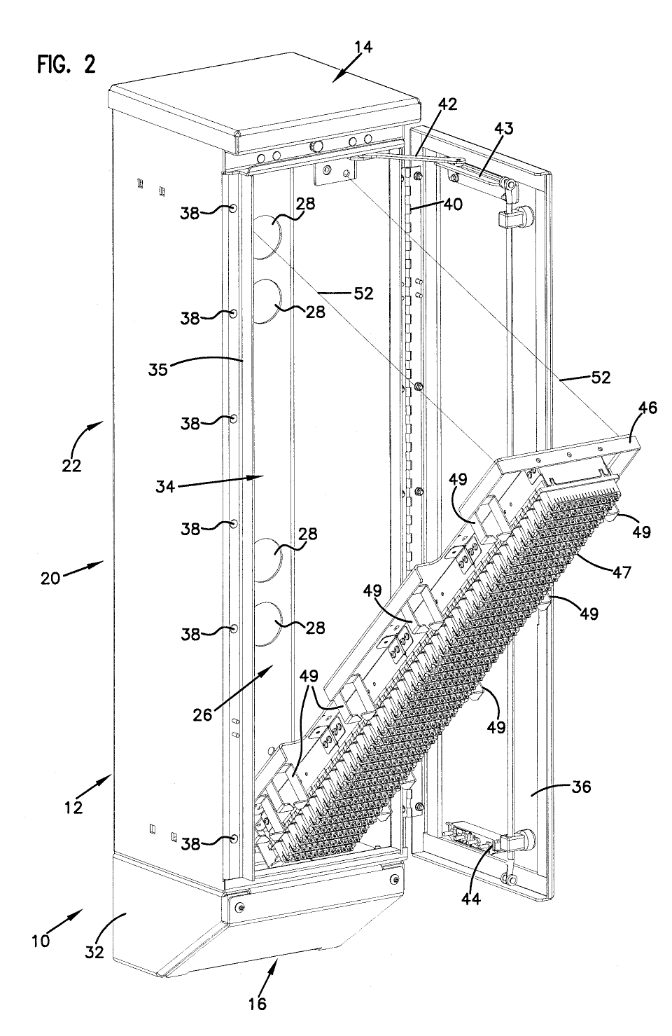

In the embodiment shown, the panel hinge 48 connects to the cross-connect panel 46 along the bottom 16 of the housing 12, and a latch 50 connects to the cross-connect panel 46 near the top 14 of the housing. The latch 50 retains the cross-connect panel 46 within the interior area 26. When the latch 50 is released, as is shown in FIG. 2, the cross-connect panel 46 is allowed to pivot outwardly through the doorway 34. In other embodiments, the panel hinge 48 and latch 50 can be rearranged, causing the cross-connect panel 46 to pivot out from the interior area 26 differently from the manner shown in FIG. 2. The pivoting of the cross-connect panel 46 allows access into the rear portion of the interior area 26 of the housing 12, behind the panel. Pivoting the cross-connect panel 46 also allows access to electrical components mounted to the rear surface of the panel.

Optionally, one or more chains 52 connected to the panel 46 limit the pivotal movement of the panel based on the length of and slack in the chains. In the embodiment shown in FIG. 2, the chains 52 connect from a position near the latch 50 at the top of the interior area 26 of the housing 12.

The cross-connect panel 46 is also removable from the interior area 26 by releasing the panel hinge 48 and the latch 50. In certain embodiments, the panel hinge 48 includes a removable pin, thereby allowing a field user (e.g. a technician) of the expansion cross-connect enclosure 10 to easily install or remove an entire cross-connect panel 46 within the housing 12. To remove the cross-connect panel 46, a technician generally will disconnect all wires (e.g. jumpers extending to the cross-connect panel 46 from/to the access openings 28, and will disengage the hinge 48 and latch 50. The chains 52 are then disconnected, and the cross-connect panel 46 is removed from the interior area 26 of the housing 12. A reverse process is used to install a cross-connect panel 46 within the housing 12.

Referring now to FIGS. 9-13, additional details regarding removal and configuration of the access door 36 are described, according to a possible embodiment of the present disclosure. In the embodiment shown, the access door 36 is reversible, in that the door hinge 40 can be located on either the left side or the right side of the door frame 35. The access door 36 is resiliently connected to the door hinge 40, such as by screws, welding, or other means. The door hinge 40 is then connected to a side of the door frame 35 at the mounting locations 38 by a plurality of removable bolts 54.

To reverse the location of the door hinge 50 (and the direction of pivoting of the access door 36), the removable bolts 54 are removed from the door frame 35 and door hinge 40. The guide 42 is also removed from the slot 43. The access door 36 is then inverted, such that the door hinge 40 is located at an opposite side.

Once the access door is inverted, the slot 43 is at the bottom of the door and the connection point 44 is at the top of the door. A technician reverses the locations of the slot 43 and the connection point 44 by removing and interchanging the positions of these items. Preferably, the slot 43 and connection point 44 are located at equivalent positions at opposed ends of the access door 36, and a common set of mounting holes can be used to interchange their positions. The guide 42 is reinserted into the slot 43, and the removable bolts 54 are reconnected through the door hinge 40 and the mounting locations (now using those on the opposite side from where the access door 36 was originally detached).

Referring now to FIGS. 1-13 generally, in use, the expansion cross-connect enclosure 10 provides a versatile expansion system for an existing cross-connect system. For example, the expansion cross-connect enclosure 10 can be arranged to receive cables through the cable access openings 28 that are located toward either side of the expansion cross-connect enclosure. Also, the access door 36 can be configured to pivot either toward the left or right, depending on the location of the door hinge 40. The access door 36 is therefore ensured to be able to pivot away from interfering with a technician routing cables between an existing cross-connect enclosure and the expansion cross-connect enclosure 10. Furthermore, the cable access openings 28 and 30 allow receipt of telecommunications signal wires either from the existing cross-connect enclosure (e.g. through the cable access openings 28) or from a separate signal wire located below the expansion cross-connect enclosure (e.g. through the cable access opening 30).

Now referring to FIGS. 14-15, mounting and use of an expansion cross-connect enclosure 10 are described according to possible embodiments of the present disclosure. FIG. 14 illustrates a cross-connect system 100 mounting of an expansion cross-connect enclosure 10 to an existing cross-connect enclosure 102. In the embodiment shown, the existing cross-connect enclosure 102 has a number of horizontal cable access openings 104, allowing a technician to route jumpers or other cables horizontally outward from the existing cross-connect enclosure 102. The existing cross-connect enclosure also includes a plurality of mounting locations 106, which correspond to locations at which the expansion cross-connect enclosure 10 can be bolted or otherwise fastened to the existing cross-connect enclosure 102.

In the embodiment shown, connecting the expansion cross-connect enclosure 10 to the existing cross-connect enclosure 102 at the mounting locations 106 causes the horizontal cable access openings 104 to align with the cable access openings 28 of the expansion cross-connect enclosure 10. A protective ring (not shown) can be installed at the joinder of the horizontal cable access opening 104 and corresponding cable access opening 28 to prevent wear of cables passing through the opening.

Preferably, the cable access openings 28 of the expansion cross-connect enclosure 10 that are selected for alignment with the horizontal cable access openings 104 of the existing cross-connect enclosure 102 are those that are near a side of the expansion cross-connect enclosure 10 opposite the side on which the door hinge 40 is mounted. In the embodiment shown, the cable access openings 28 are used which are closest to a side of the existing cross-connect enclosure 102 on which doors 108 are located, while the access door 36 of the expansion cross-connect enclosure 10 is hinged on a side away from the access doors 108 of the existing cross-connect enclosure. This allows a technician to easily feed cables through the cable access openings 28, while avoiding interference from the access door 36 (e.g. the door swinging into the technician or otherwise interfering with maintenance of the cross-connect system 100.

The expansion cross-connect enclosure 10 can be used to expand the capacity or functionality of an existing cross-connect enclosure. For example, the expansion cross-connect enclosure 10 can be used to incorporate an additional digital subscriber line (DSL) add-on module, as described in U.S. Pat. No. 7,155,004, entitled “System and Method of Delivering DSL Services”, the disclosure of which is hereby incorporated by reference in its entirety.

Referring now to FIG. 15, a further cross-connect system 200 is shown. In this cross-connect system, two expansion cross-connect enclosures 10, 10′ are mounted to opposing sides of an existing cross-connect enclosure 202. The expansion cross-connect enclosures 10, 10′ can be mounted in a manner analogous to that shown in FIG. 12; however, it can be seen that the access door 36 of each enclosure 10, 10′ is arranged to pivot away from a front portion of the existing cross-connect enclosure 202 having its own access doors 204. This arrangement allows the access door of the expansion cross-connect enclosure 10 to pivot away from the area in which a technician is likely working, because it is likely that the technician will likely be attempting to access the interior areas of the expansion cross-connect enclosures 10, 10′ and the existing cross-connect enclosure 202 for interconnection of telecommunications signals. Because the enclosures 10, 10′ are mounted to opposite sides of the existing cross-connect enclosure, the door hinge 40 for the access doors 36 of the respective enclosures 10, 10′ are located at opposite edges of the corresponding door frame 35. One or both of the access doors 36 is therefore rearranged in accordance with the methodology described in conjunction with FIGS. 9-13.

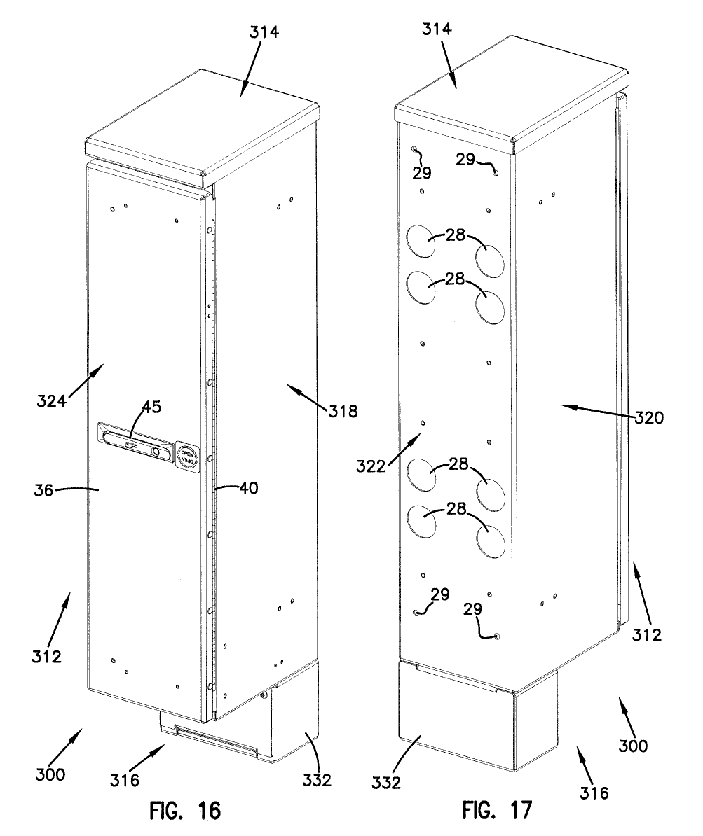

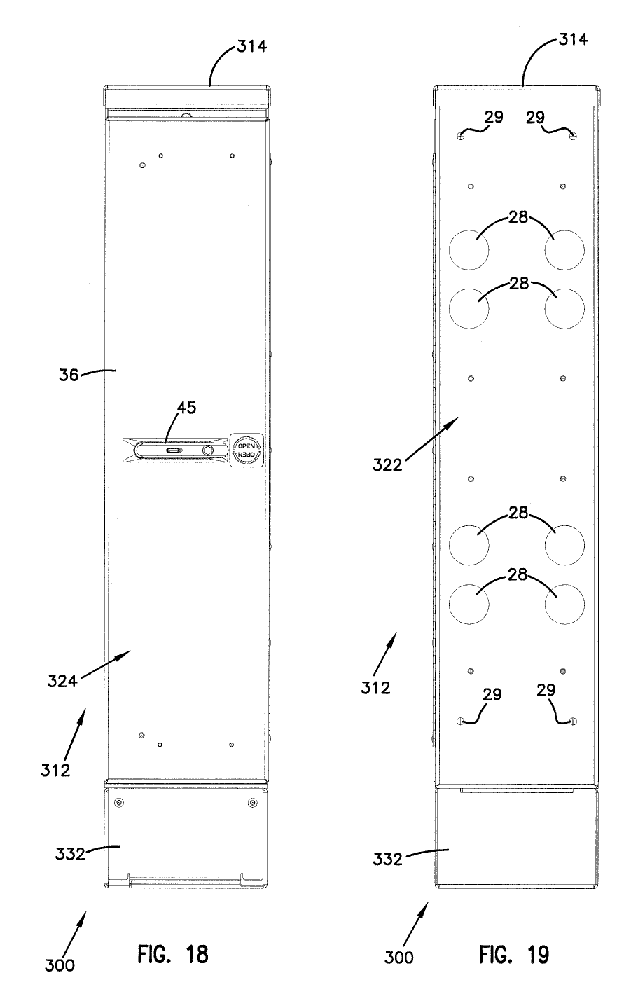

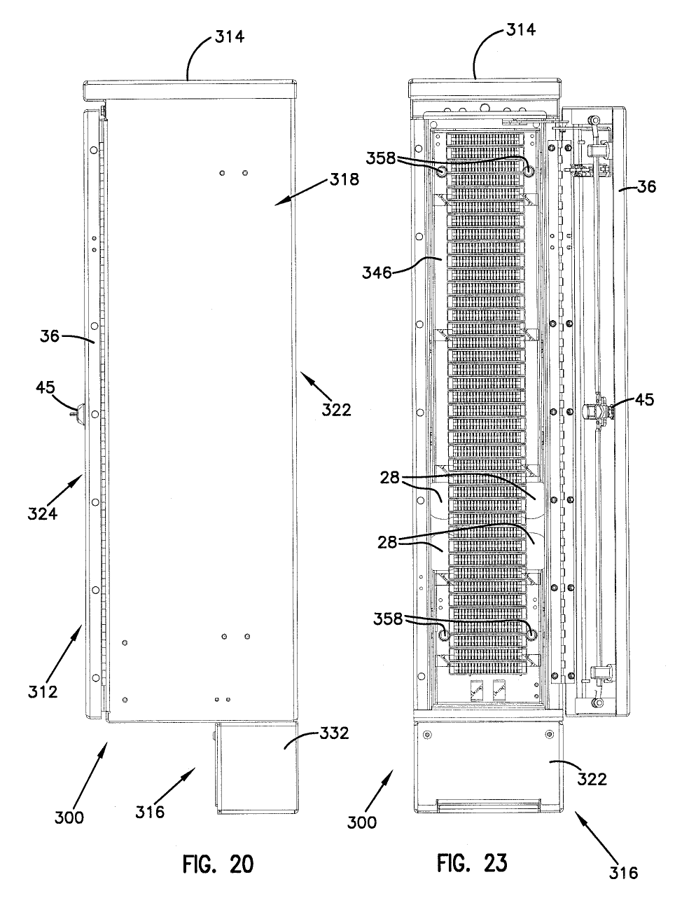

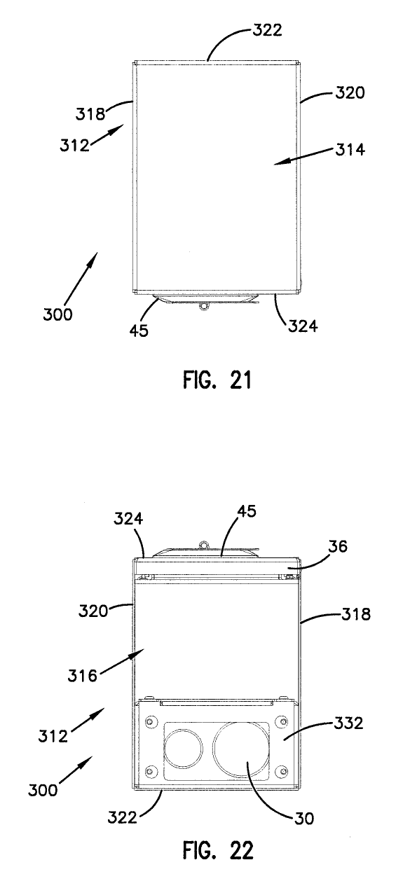

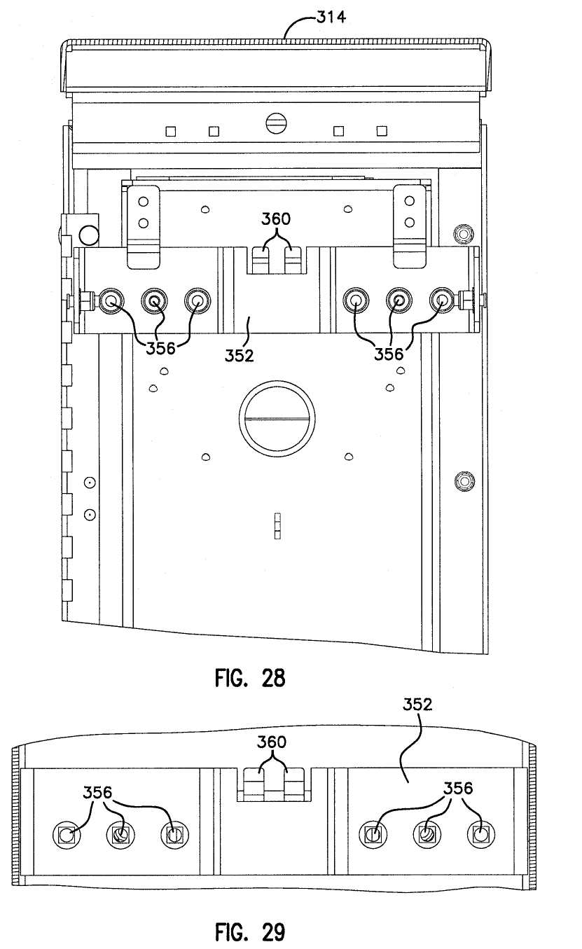

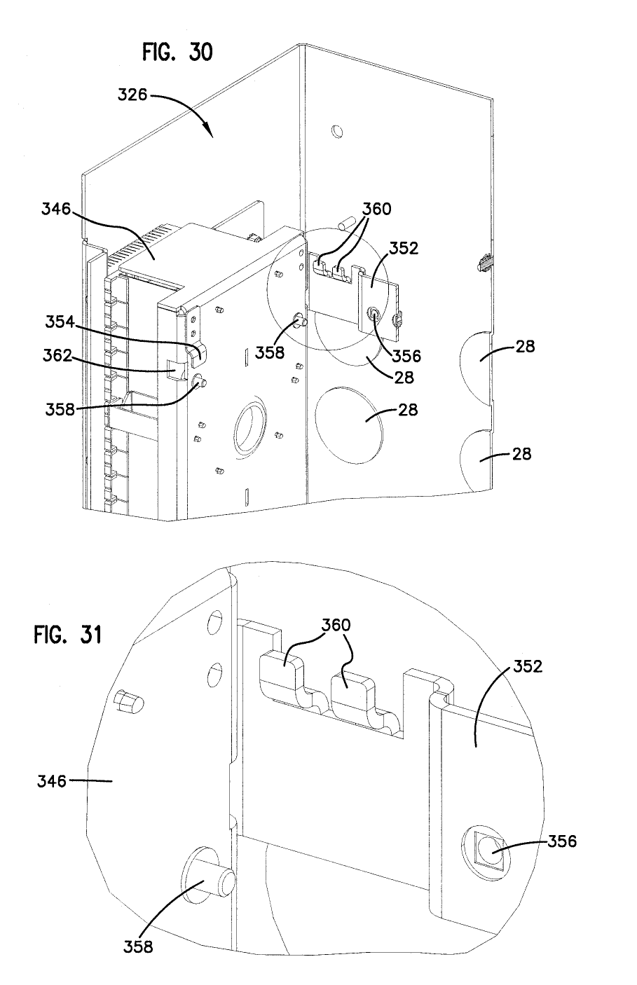

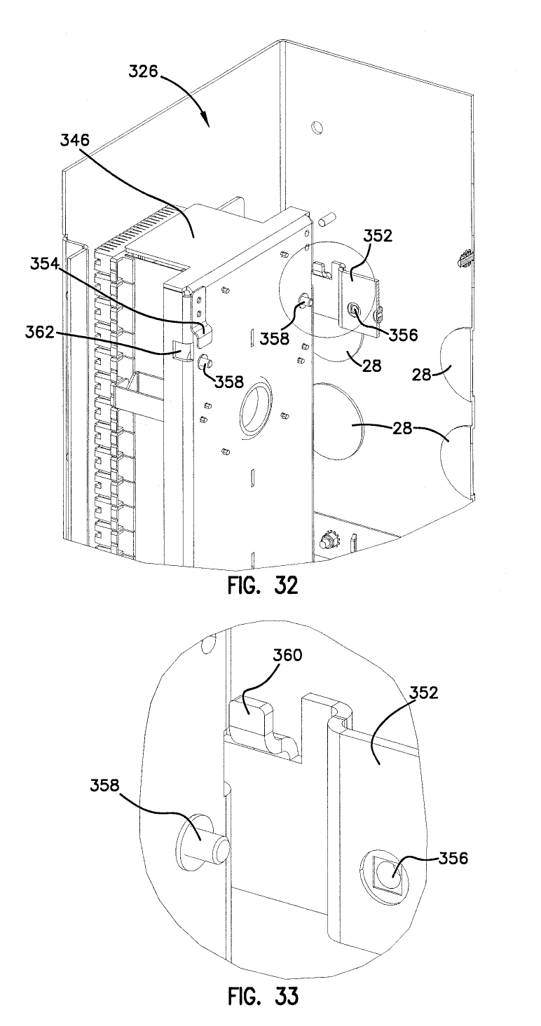

In further embodiments, the expansion cross-connect enclosure 300 of FIGS. 16-33, below, can be used in place of or in combination with the expansion cross-connect enclosure 10.

Referring now to FIGS. 16-33, a further embodiment of an expansion cross-connect enclosure 300 is shown. The cross-connect enclosure 300 generally includes similar features to the expansion cross-connect enclosure 10 of FIGS. 1-13, with a modified arrangement for mounting a cross-connect panel within. The expansion cross-connect enclosure 300 includes a housing 312, which generally corresponds to the housing 12 of the enclosure 10 of FIGS. 1-13. The housing 312 also has a top 314, a bottom 316, a right side 318, a left side 320, a rear 322, and a front 324, which define an interior area 326. The bottom 316 includes, in this embodiment, a mounting extension 332 used to reduce exposure of the internal components to environmental conditions. The mounting extension 332 is generally rectangular in shape, compared to the angled shape of the mounting extension 32 of FIGS. 1-13. The mounting extension 332 can at least partially cover the cable access opening 30 in the bottom 316 to reduce exposure of the internal components to environmental conditions, while allowing routing of jumpers or other cables through the opening 30.

In the embodiment shown, the cross-connect enclosure 300 includes an alternative mounting configuration for a cross-connect panel 346 used within the enclosure 312. In general, the mounting configuration allows the cross-connect panel 346 to be mounted in a variety of forward-facing mounting positions (seen in FIGS. 23-25), where the cross-connect panel 346 faces the access door 36, or a sideways-facing mounting position, where the cross-connect panel 346 is perpendicular to the access door.

In this embodiment, the cross-connect enclosure 300 includes a mounting assembly 350 on the rear 322, within the interior area 326. The mounting assembly 350 includes a pair of mounting bars 352 positioned to connect to the cross-connect panel 346 near top and bottom ends of the panel. The cross-connect panel 346 generally corresponds to the panel 46 of FIGS. 1-13, but includes mounting structures complementary to the mounting assembly 350 in place of the hinge and wire construction of the panel 10. The mounting bars 352 of the mounting assembly 350 include at least a portion spaced from the rear 322 of the enclosure 300 to receive flanged tabs 354 incorporated on the rear side of the cross-connect panel 346 when the panel is mounted in a forward-facing position. The mounting bars 352 also include a set of mounting bolt receiving locations 356, which are arranged to receive mounting bolts 358 inserted through the cross-connect panel 346 for affixing the cross-connect panel 346 within the housing 312, in any of a variety of predetermined locations based on the locations of the receiving locations and associated mounting bolts.

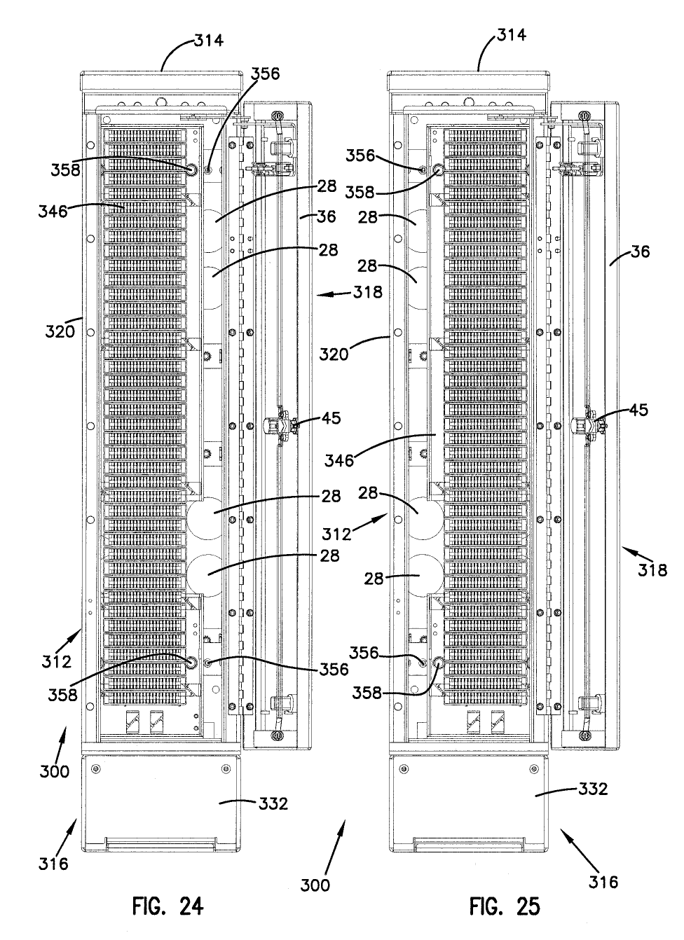

In the embodiment shown, particularly as illustrated in FIGS. 27-29, each of the mounting bars 352 includes three pairs of mounting bolt receiving locations 356, totaling 12 mounting bolt receiving locations for the four mounting bolts 358 in the panel 346. These mounting bolt receiving locations 356 are arranged to allow mounting of the cross-connect panel 346 in centered (FIG. 23), leftward (FIG. 24), and rightward (FIG. 25) mounting positions along the rear 322 of the housing 312. Mounting the panel 346 in each of these locations allows service personnel to easily pass cables through cable access openings 28 in the rear 322 of the housing 312, as described in conjunction with the enclosure 10 above.

Different numbers or positions for the mounting bolt receiving locations 356 and mounting bolts 358 are possible as well, and can provide different mounting positions for the cross-connect panel than those shown. Placement of the mounting bolt receiving locations (and the resulting mounting position of the panel 346) can be varied to provide convenient access to jumpers passing into the interior area 326 of the enclosure 300.

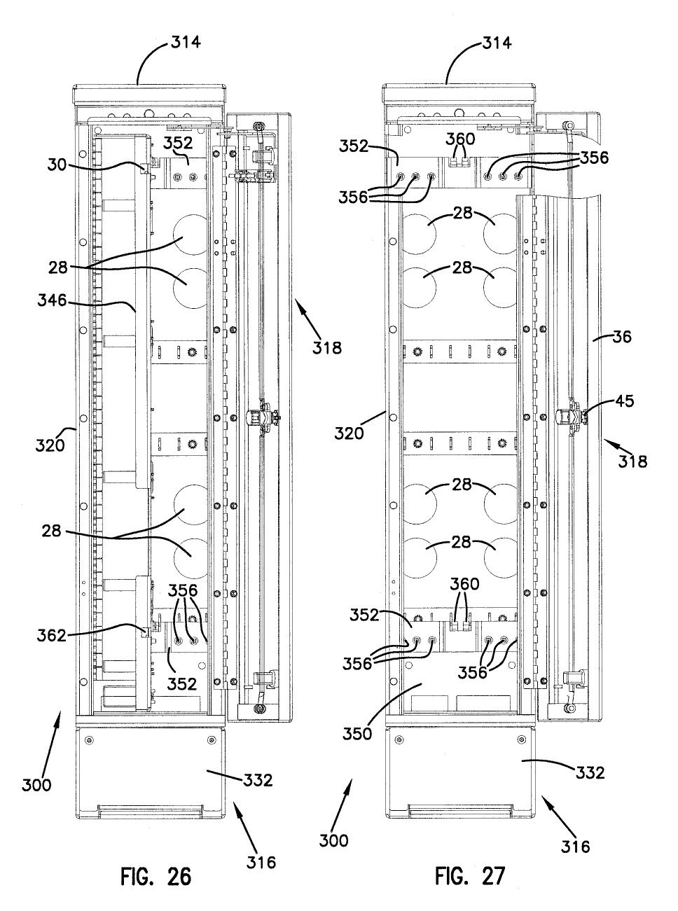

As seen in FIGS. 26 and 30-33, to allow mounting of the cross-connect panel 346 in a sideways position within the panel 300, the mounting assembly 350 also includes tabs 360 positioned generally centrally and along a top edge of each of the mounting bars 352. The tabs 360 are flared toward the access door 36 and spaced to be inserted into openings 362 located along one or both edges of the cross-connect panel 346. The cross-connect panel 346 is held in the perpendicular position within the enclosure (facing either toward the left or right) by the tabs 360.

In use, technicians or other service personnel seeking easier access to cables, openings or other elements residing behind (or to the side of) the cross-connect panel 346 can detach the panel from the enclosure 300 by removing the mounting bolts 358 from the mounting bolt receiving locations 356 and lifting the panel 346 to disengage the flanged tabs 354 from the mounting bars 354. The panel 346 can then be rotated in either direction for sideways mounting within the enclosure 300 for access to jumpers, cable access openings, or other elements behind the panel. When service is completed, the panel 346 can be returned to its forward-facing position and the mounting bolts can be reinserted into the selected mounting bolt receiving locations 356, based on the desired placement of the panel (center, left, right) along the rear 322 of the enclosure 300.

The expansion cross-connect enclosure 300 can be used analogously to the enclosure 10 with respect to expanding the capacity or functionality of existing cross-connect panels, as described in conjunction with FIGS. 14-15. The expansion cross-connect enclosure includes analogous reversibility and adjustability for mounting to existing enclosures. The panel 346 can be arranged in a forward mounting position along the rear 322 in a position providing easiest access to the desired openings 28 from an existing cross-connect enclosure, as described above in FIGS. 14-15 in conjunction with another embodiment of the expansion cross-connect panel. Furthermore, by allowing pivotal movement of the panel 346, the area behind the panel within the interior 326 can be reached with minimal slack allowed in the jumpers connected to the panel.

Although the expansion cross-connect enclosures of the present disclosure have been shown in the Figures and described as having certain dimensions, it is recognized that the present disclosure is not so limited. The expansion cross-connect enclosures could be of varying dimensions, and could include additional connection circuitry internal to the enclosure (e.g. on the cross-connect panel 46, 346). Furthermore, different types of fasteners or hinges can be used beyond those specifically shown in the figures. Furthermore, although the term “jumper” is used herein to denote cables interconnected among the existing cross-connect enclosure and an expansion cross-connect enclosure, the term is intended herein to encompass any type of voice or data cable, such as a broadband cable.

Through use of the expansion cross-connect enclosures of the present disclosure, additional capacity and functionality can be added to existing telecommunications networks. For example, broadband services (e.g. DSL service) can be added to an existing voice network through cross-connection to a DSLAM using the expansion cross-connect enclosures disclosed herein.

The above specification, examples and data provide a complete description of the manufacture and use of the composition of the invention. Since many embodiments of the invention can be made without departing from the spirit and scope of the invention, the invention resides in the claims hereinafter appended.

1. An expansion cross-connect enclosure comprising:
(a) a housing having a front, a rear, a top, a bottom, and left and right sides, the housing having a doorway at the front;
(b) a cross-connect panel pivotally connected to the housing by a panel hinge, the cross-connect panel affixed within the housing by a latch;
(c) an access door covering the doorway, the access door pivotally connected across the front by a door hinge; and
(d) cable access openings in the rear of the housing positioned to be aligned with horizontal cable access openings of an existing cross-connect enclosure.

2. The expansion cross-connect enclosure of claim 1, wherein the door hinge is configured to be connectable at either of opposing sides of a door frame surrounding the doorway.

3. The expansion cross-connect enclosure of claim 1, further comprising a cable access opening in the bottom of the housing.

4. The expansion cross-connect enclosure of claim 1, wherein the cable access openings in the rear of the housing allow connection of jumpers external to the expansion cross-connect enclosure.

5. The expansion cross-connect enclosure of claim 1, wherein the panel hinge mounts to an interior surface of the bottom of the housing.

6. The expansion cross-connect enclosure of claim 5, further comprising a chain connected between the cross-connect panel and the housing, the chain limiting a pivoting range of the cross-connect panel.

7. The expansion cross-connect enclosure of claim 1, further comprising a locking latch on the access door on a side opposite the door hinge.

8. The expansion cross-connect enclosure of claim 1, wherein the cross-connect panel is removably mounted to the housing by the panel hinge.

9. The expansion cross-connect enclosure of claim 1, wherein the cable access openings are punch-out openings.

10. A method of expanding capacity of a cross-connect system, the method comprising:
mounting a housing of an expansion cross-connect enclosure to an existing cross-connect enclosure, such that horizontal jumper access openings of the existing cross-connect enclosure align with access openings in a rear of the expansion cross-connect enclosure, the access openings located on the rear of the panel toward a side opposite an access door of the expansion cross-connect enclosure; and
connecting a jumper to a cross-connect panel of the expansion cross-connect enclosure, the cross-connect panel pivotally connected to the housing by a panel hinge, the cross-connect panel affixed within the housing by a latch.

11. The method of claim 10, further comprising mounting the access door to the housing of the expansion cross-connect enclosure to pivot away from an access door of the existing cross-connect enclosure.

12. The method of claim 10, further comprising:
releasing the latch; and
pivoting the cross-connect panel of the expansion cross-connect enclosure.

13. The method of claim 12, further comprising:
disconnecting the jumper;
releasing the panel hinge; and
removing the cross-connect panel from the expansion cross-connect enclosure.

14. The method of claim 10, further comprising:
disconnecting a door hinge connecting the access door to a first side of a door frame of the expansion cross-connect panel;
reconnecting the door hinge on a second side of the door frame, the second side opposite the first side.

15. The method of claim 10, further comprising locking the access door to the expansion cross-connect panel.

16. A cross-connect system comprising:
an existing cross-connect enclosure having a horizontal cable access opening on at least a first side and an access door on a second side adjacent the first side; and
an expansion cross-connect enclosure mounted to the existing cross-connect enclosure, the expansion cross-connect enclosure including:
a housing having a front, a rear, a top, a bottom, and left and right sides, the housing having a doorway at the front;
a cross-connect panel pivotally connected to the housing by a panel hinge, the cross-connect panel affixed within the housing by a latch;
an access door covering the doorway, the access door pivotally connected across the front by a door hinge; and
a cable access opening in the rear of the housing positioned to be aligned with the horizontal cable access opening of the existing cross-connect enclosure.

17. The cross-connect system of claim 16, wherein the access door of the expansion cross-connect enclosure pivots away from the second side of the existing cross-connect enclosure.

18. The cross-connect system of claim 16, wherein the cable access opening is a punch-out opening.

19. The cross-connect system of claim 16, wherein the cable access opening allows connection of jumpers from a cross-connect panel in the existing cross-connect enclosure to the cross-connect panel in the expansion cross-connect enclosure.

20. The cross-connect system of claim 16, wherein the cross-connect panel is removably mounted to the housing by the panel hinge.

21. An expansion cross-connect enclosure comprising:
(a) a housing having a front, a rear, a top, a bottom, and left and right sides, the housing having a doorway at the front;
(b) a cross-connect panel connectable to the housing via a mounting assembly, the mounting assembly including a plurality of mounting positions;
(c) an access door covering the doorway, the access door pivotally connected across the front by a door hinge; and
(d) cable access openings in the rear of the housing positioned to be aligned with horizontal cable access openings of an existing cross-connect enclosure.

22. The expansion cross-connect enclosure of claim 21, wherein the plurality of mounting positions includes a plurality of forward-facing mounting positions.

23. The expansion cross-connect enclosure of claim 21, wherein the mounting assembly includes a plurality of mounting bars.

24. The expansion cross-connect enclosure of claim 23, wherein each of the plurality of mounting bars includes a plurality of mounting bolt receiving locations arranged to receive mounting bolts connected to the cross-connect panel.

25. The expansion cross-connect enclosure of claim 23, wherein each of the plurality of mounting bars includes a tab arranged to receive an opening in the cross-connect panel.

26. The expansion cross-connect enclosure of claim 21, wherein the plurality of mounting positions includes at least one sideways mounting position.

27. The expansion cross-connect enclosure of claim 21, wherein at least one of the plurality of mounting positions allows access to cable access openings in a rear of the housing.

28. A method of expanding capacity of a cross-connect system, the method comprising:
mounting a housing of an expansion cross-connect enclosure to an existing cross-connect enclosure in one of a plurality of mounting positions, such that horizontal jumper access openings of the existing cross-connect enclosure align with access openings in a rear of the expansion cross-connect enclosure, the access openings located on the rear of the panel toward a side opposite an access door of the expansion cross-connect enclosure; and
connecting a jumper to a cross-connect panel of the expansion cross-connect enclosure, the cross-connect panel connectable to the housing via a mounting assembly and at a plurality of mounting positions.

29. The method of claim 28, further comprising connecting the cross-connect panel to the mounting assembly at one of the plurality of mounting positions.

30. The method of claim 29, wherein the one of the plurality of mounting positions is a forward-facing mounting position.

31. A cross-connect system comprising:
an existing cross-connect enclosure having a horizontal cable access opening on at least a first side and an access door on a second side adjacent the first side; and
an expansion cross-connect enclosure mounted to the existing cross-connect enclosure, the expansion cross-connect enclosure including:
a housing having a front, a rear, a top, a bottom, and left and right sides, the housing having a doorway at the front;
a cross-connect panel connectable to the housing via a mounting assembly, the mounting assembly including a plurality of mounting positions;
an access door covering the doorway, the access door pivotally connected across the front by a door hinge; and
a cable access opening in the rear of the housing positioned to be aligned with the horizontal cable access opening of the existing cross-connect enclosure.

32. An expansion cross-connect enclosure comprising:
(a) a housing having a front, a rear, a top, a bottom, and left and right sides, the housing having a doorway at the front;
(b) a cross-connect panel detachably connected within the housing at the rear of the housing;
(c) an access door covering the doorway, the access door pivotally connected across the front by a door hinge; and
(d) cable access openings through the rear of the housing positioned to be aligned with horizontal cable access openings of an existing cross-connect enclosure.

33. The expansion cross-connect enclosure of claim 32, wherein the cross-connect panel is pivotally connected to the housing by a panel hinge and affixed within the housing by a latch.

34. The expansion cross-connect enclosure of claim 32, wherein the cross-connect panel is connected to the housing via a mounting assembly, the mounting assembly including a plurality of mounting positions.
